(19) United States
(12) Patent Application Publication
(10) Pub. No.: US 2009/0050468 A1
(43) Pub. Date: Feb. 26, 2009

(54) CONTROLLED SURFACE OXIDATION OF ALUMINUM INTERCONNECT

(75) Inventors: A. MILLER ALLEN, Oakland, CA (US); Ashish Bodke, San Jose, CA (US); Yong Cao, San Jose, CA (US); Anthony C-T Chan, Los Altos Hills, CA (US); Jianming Fu, Palo Alto, CA (US); Zheng Xu, Pleasanton, CA (US); Yasunori Yokoyama, Kawaguchi City (JP)

Correspondence Address: LAW OFFICES OF CHARLES GUENZER;ATTN: APPLIED MATERIALS, INC., 2211 PARK BOULEVARD, P.O. BOX 60729, PALO ALTO, CA, 94306, US

(73) Assignee: Applied Materials, Inc., Santa Clara, CA (US)

(21) Appl. No.: 11/843,508

(22) Filed: Aug. 22, 2007

(51) Int. Cl. C23C 14/34; C23C 14/54

(52) U.S. Cl. 204/192.1; 204/298.02; 204/298.09

(57) ABSTRACT

An aluminum interconnect metallization for an integrated circuit is controllably oxidized in a pure oxygen ambient with the optional addition of argon. It is advantageously performed as the wafer is cooled from above 300° C. occurring during aluminum sputtering to less than 100° C. allowing the aluminized wafer to be loaded into a plastic cassette. Oxidation may controllably occur in a pass-through chamber between a high-vacuum and a low-vacuum transfer chamber. The oxygen partial pressure is advantageously in the range of 0.01 to 1 Torr, preferably 0.1 to 0.5 Torr. The addition of argon to a total pressure of greater than 1 Torr promotes wafer cooling when the wafer is placed on a water-cooled pedestal. To prevent oxygen backflow into the sputter chambers, the cool down chamber is not vacuum pumped during cooling and first argon and then oxygen are pulsed into the chamber.

### FIELD OF THE INVENTION

The invention relates generally to sputtering in the formation of integrated circuits. In particular, the invention relates to the post-treatment of sputtered aluminum used in forming interconnects.

### BACKGROUND ART

Sputtering, alternatively called physical vapor deposition (PVD), is the most prevalent method of depositing layers of metals and related materials in the fabrication of silicon integrated circuits. In one type of DC magnetron sputtering most used in commercial production, the wafer to be sputter coated is placed within a vacuum chamber in opposition to a target of the metal to be sputtered. Argon working gas is admitted into the vacuum chamber. When the target is negatively biased with respect to the chamber wall or its shields, the argon is excited into a plasma and sputters metal atoms from the target, some of which strike the wafer and form a coating of the metal on it. A magnetron placed in back of the target includes magnetic poles of opposite polarities to project a magnetic field into the chamber adjacent the sputtering face of the target to increase the plasma density and the sputtering rates. The wafer may be electrically biased to assist in coating into deep and narrow vias. Other forms of sputtering are possible and may include RF inductive coils, auxiliary magnets, and complexly shaped targets.

Sputtered aluminum continues to be used as the metallization to form both vertical and horizontal interconnects. It is understood that the aluminum may be alloyed. Typical intended alloys are copper, magnesium and silicon, which may be present in amounts of less than 10 at % and usually less than 5 at %. A standard aluminum alloy in semiconductor fabrication includes 0.5 wt % copper. Other metals are usually not present to more than 1 at %.

A simple via structure utilizing aluminum metallization is illustrated in the cross-sectional view of FIG. 1. A lower dielectric layer 10 has a conductive feature 12, for example, of aluminum formed in its surface and requiring to be electrical connected. An upper dielectric layer 14 is deposited over the lower dielectric layer 10 and its conductive feature 12 and a via hole 16 is etched through the upper dielectric layer 14 down to the conductive feature 12. An aluminum layer 18 is sputtered to fill the via hole 16 and to form a generally planar layer on top of a field region 20 at the top surface of the upper dielectric layer 14. The aluminum sputtering may include different sputtering steps and even separate sputtering chambers for different sub-layers, but most typically the last portion of the aluminum sputtering is performed with the silicon wafer being held at a moderately high temperature, for example, 400° C. to promote reflow of the aluminum to both fill the via hole 16 and to planarize the upper surface of the aluminum layer 18. If the via is being formed in the lowest level of metallization, the lower dielectric layer 10 is replaced by a silicon layer and the conductive feature may be a doped silicon region with additional contact, barrier, or gate oxide regions typically being formed between the silicon conductive feature 12 and the aluminum-filled via 16.

At this point, the aluminum layer 18 presents an unpatterned, undefined, and generally planar upper surface with most deviations from planarity arising from the conformal deposition onto underlying features. The field thickness of the aluminum layer 18 over an upper surface 20 of the dielectric layer 14 determines the thickness of the horizontal interconnect, which is typically in the range of 160 to 1000 nm. As illustrated in the cross-sectional view of FIG. 2, the aluminum layer 18 outside of the via hole 16 is selectively etched down to the upper surface 20 of the dielectric layer 14 or to a thin barrier layer on its upper surface 20. The patterning of the photolithographic etching forms generally long and narrow horizontal electrical interconnects connected to multiple aluminum-filled vias or to the next level of metallization. To assist the photolithography defining the patterning of the etching, an anti-reflective coating (ARC) 22 of, for example, titanium nitride (TiN) is deposited over the unpatterned aluminum layer 18 of FIG. 1.

Aluminum may be sputtered in many different chambers and platforms. For example, an aluminum deposition system 30 illustrated in schematic plan view in FIG. 3 is based on the Endura platform available from Applied Materials, Inc. of Santa Clara, Calif. Wafers 32 are carried in cassettes 34, for example, plastic FOUPs, placed in two load lock chambers 36, 38 separated by slit valves from an inner transfer chamber 40 held at a moderately low pressure. Once the cassette 34 has been loaded into the load lock chamber 36, 38 and the load lock chamber 36, 38 has been pumped down, an inner robot 42 in the inner transfer chamber 40 can transfer wafers 32 between the cassettes 34 in either of the load lock chambers 36, 38 and any of several processing chambers 46, 48, 50, 52 located around the inner transfer chamber 40. These inner chambers typically perform pre-processing not requiring an ultra-high vacuum, such as orienting, degassing, and pre-cleaning. Thus, the inner transfer chamber 40 may need to be pumped to a base pressure of only about 1 milliTorr. The inner robot 42 can also transfer wafers 32 to and from two pass through chambers 54, 56. An outer robot 60 in an outer transfer chamber 62 can also transfer wafers 32 to and from the two pass through chamber 54, 66. Unillustrated slit valves isolate each of the pass through chamber 54, 56 from the inner and outer transfer chambers 40, 62 thereby allowing the outer transfer chamber 62 to be held at a lower base pressure than the inner transfer chamber 42, for example, about 1×10⁻⁸ Torr. The low base pressure is primarily needed to prevent oxidation of sputter deposited films. Arranged around the outer transfer chamber 62 and isolated from it by respective slit valves are an aluminum PVD chamber 64 and a barrier PVD chamber 66, for example, sputtering titanium. Other processing chambers 68, 70 may also be arranged around the outer transfer chamber 62, such as a different type of aluminum sputtering chamber, for example, for aluminum seed rather than aluminum fill, or a duplicate aluminum sputtering chamber for increased throughput. All these chambers 64, 66, 68, 70 may benefit from the high vacuum levels afforded by the outer transfer chamber 62.

The pass through chambers 54, 56 provide two-directional flow of wafers between the two transfer chambers 40, 62. Further, they may be adapted to perform some of the secondary processing. The wafer 32 after the final aluminum sputter deposition may be at a relatively high temperature of about 400° C. and may require no further substantive processing before being returned to one of the cassettes 34. The blades attached to the robots 42, 60 are designed to withstand these high temperatures. However, the cassettes 34 are typically composed of a plastic material such that wafers 32 inserted into the cassettes 34 should be at a relatively low temperature, for example, no more than 100° C. Accordingly, the pass through chamber 56 in the output direction may be adapted to act as a cool down chamber 80, schematically illustrated in the cross-sectional view of FIG. 4, formed in a vacuum chamber 82 integral with the transfer chambers 40, 62. The wafers 32 are cooled down to the lower temperature in the cool down chamber 80 after sputtering and before being returned to the cassettes 34. Wafer ports 84, 86 of sufficient lateral width to pass the wafers 32 are formed in opposed walls next to the transfer chamber 40, 62. The wafer ports 84, 86 are selectively sealed by elongated valve heads 88, 90 connected to shafts 92, 94 driven by actuators 96, 98 to form respective slit valves. Similar slit valves are formed between the transfer chambers 40, 62 and the processing chambers 46, 48, 50, 52, 64, 66, 68, 70 and the load lock chambers 36, 38.

The blades of the two robots 42, 60 can enter the respectively opened wafer port 84, 86 to transfer the wafer 32 to and from a pedestal 100. Cooling water from a chiller 102 passes through a cooling channel 104 in the pedestal 100 to maintain it at a low temperature appropriate for cooling the wafer 32. Argon is supplied into the cool down chamber 80 from an argon gas source 106 through a gas valve 108. Typically, the argon gas source 106 also supplies argon to the sputter chambers 62, 66 during their sputter operation.

The hot wafer 32 may be cooled during a cool down period of 30 to 60 seconds in an ambient of argon at a pressure of about 1 to 2 Torr to promote thermal transfer to the cooled pedestal 100. It is typical for the cool down chamber 80 to not be continuously pumped after it has been rough pumped. Instead, after the hot wafer 32 has been transferred to the cool down chamber 80 from the outer transfer chamber 62, the intermediate slit valve 90 is closed and the requisite amount of argon is gated into the cool down chamber 80 through the gas valve 108, whereafter the supply is interrupted or decreased and the argon remains in the cool down chamber 80 during cool down. At the end of cool down, the slit valve 88 to the inner transfer chamber 40 is opened. The cool down chamber 80 is always rough pumped by a mechanical (dry rough) pump to a pressure of about 10 microTorr. Any extra argon is released through an open slit valve into one of the transfer chambers 40, 62, which are being continuously pumped by cryopumps.

The process described above has been practiced in its fundamentals for many years. However, as device sizes shrink, the thickness of the aluminum layers forming the horizontal interconnects has also shrunk. The ability of these thinner aluminum layers to withstand both intrinsic stress and applied stress, such as occurs in thermal cycling, diminishes with film thickness. Nonetheless, the existing requirements must be satisfied for film resistivity and reflectivity. The reflectivity requirement simplifies the photolithography. Defects arising from film stress affecting the surface topography of the film include hillocks 10, illustrated in FIGS. 1 and 2, which are extrusions extending out of the plane of the film) and grain grooves, which may be deep grooves 112 formed in the aluminum film surface. Stress upon metal layers resulting from the film deposition process, film cooling, and subsequent thermal cycling in annealing or dielectric can create defects in the metal layer. These defects greatly affect device reliability and device yield by compromising the film planarity necessary to reliably etch the film to a desired thickness as well as to deposit subsequent device metal and dielectric layers in a planar form.

### SUMMARY OF THE INVENTION

An aluminum film for an aluminum interconnect in an integrated circuit is controllably oxidized in a ambient containing only oxygen as the active component. The oxidation may occur at temperatures over 100° C. as the substrate is cooled from its sputtering temperature, such as over 300° C., to less than 100° C. At the lower temperature, the substrate may be returned to a plastic cassette.

The partial fraction of oxygen may be in a range of 0.01 to 1 Torr. A preferable lower limit is 0.1 Torr. A preferable upper limit is 0.5 Torr. Additionally, an inactive gas such as argon or helium may be added to promote cooling. A total pressure may be in the range of 1 to 5 Torr or higher.

The oxidation may be performed in a cool down chamber isolatable between two transfer chambers around which are located multiple processing chambers for forming the interconnect.

The supply of argon and oxygen into the oxidizing cool down chamber may be controlled to prevent the back flow of oxygen through the argon lines into the sputter chambers and transfer chamber associated therewith. In one embodiment, the cool down chamber is vacuum pumped before cool down but not vacuum pumped during the supply of argon and oxygen or during the cool down. A controlled amount of argon is supplied to the cool down chamber. Its supply is stopped and then a controlled amount of oxygen supplied.

Oxygen contamination is avoided by assuring that the slit valve between the transfer chamber and the cool down chamber is not opened at the same time as the slit valves between the transfer chamber and the aluminum sputter chambers.

### BRIEF DESCRIPTION OF THE DRAWINGS

FIG. 1 is a cross-sectional view of an aluminum metallization in the prior art prior to etching into horizontal interconnects.

FIG. 2 is a cross-sectional view of the aluminum metallization of FIG. 1 after etching.

FIG. 3 is a schematic plan view of an aluminum sputter system.

FIG. 4 is a schematic cross-sectional view of a cool down chamber of the system of FIG. 3 usable with the invention.

FIG. 5 is a profile of a conventional sputtered aluminum film.

FIG. 6 is a cross-sectional view of a controllable oxidized aluminum metallization according to one embodiment of the invention.

FIG. 7 is a profile of a controllably oxidized sputter aluminum film of the invention.

FIG. 8 is a schematic diagram of one embodiment of the supply system including electrical and gas lines for a cool down chamber usable with the invention.

FIG. 9 is a schematic diagram of another embodiment of the supply system.

### DETAILED DESCRIPTION OF THE PREFERRED EMBODIMENTS

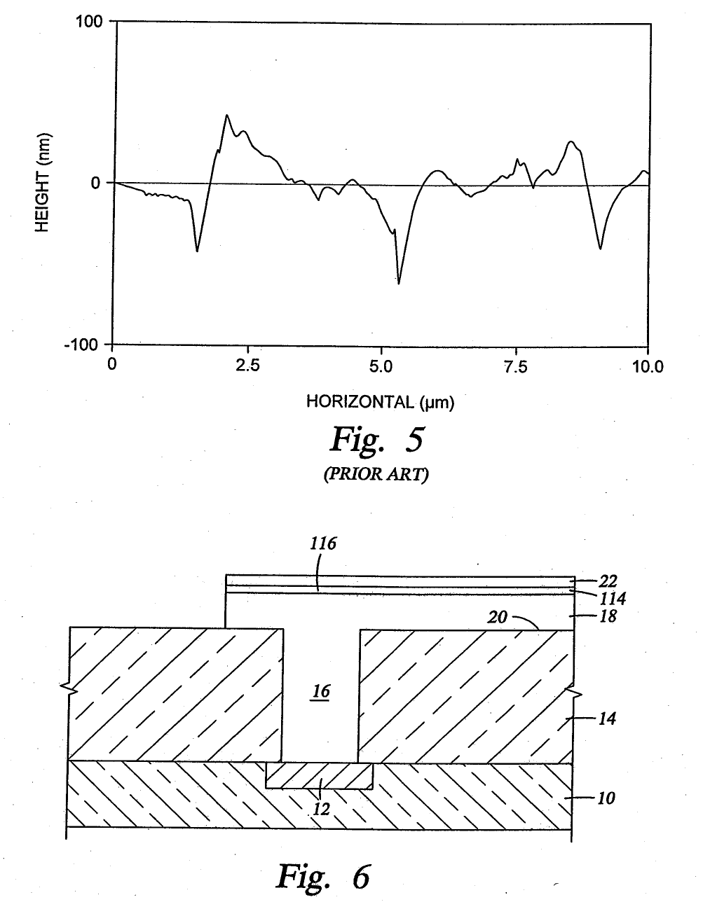

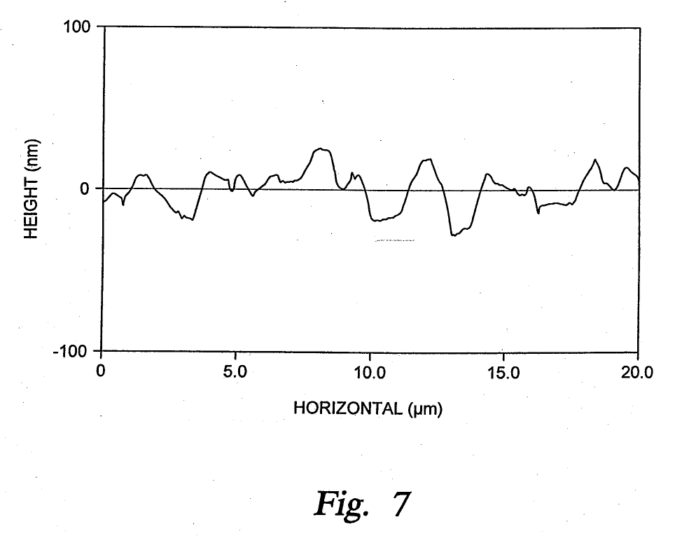

It is understood that when the wafer containing the exposed aluminum film is returned after cool down to a cassette at clean room ambient, the aluminum film is immediately oxidized to a native oxide of approximate composition Al₂O₃. We have determined that after an argon cool down to approximately 100° C., the native oxide has a thickness of about 4.2 nm and the interface with the underlying aluminum is not sharp but tends to be wavy and somewhat indistinct, that is, graded. Atomic force microscopy (AFM) performed on such an argon-cooled aluminum film produces a surface profile illustrated in FIG. 5 over a span of 10 microns. Deep grooves are apparent. The peak-to-valley roughness has a maximum value of Rₘₐₓ=101 nm and the surface exhibits an RMS roughness Rᵣₘₛ=16.5 nm. Electron micrographs show a grain size corresponding to the separation between surface grooves. Further, the planes of the individual grains appear to be uneven.

The surface topography of sputtered aluminum films can be improved by performing the cool down in a high-purity oxygen ambient to produce, as shown in the cross-sectional view of FIG. 6, an aluminum oxide layer 114 on top of the aluminum layer 18. Only after oxidation is the nitride layer 22 deposited over the oxide layer 114 in preparation for the photolithography.

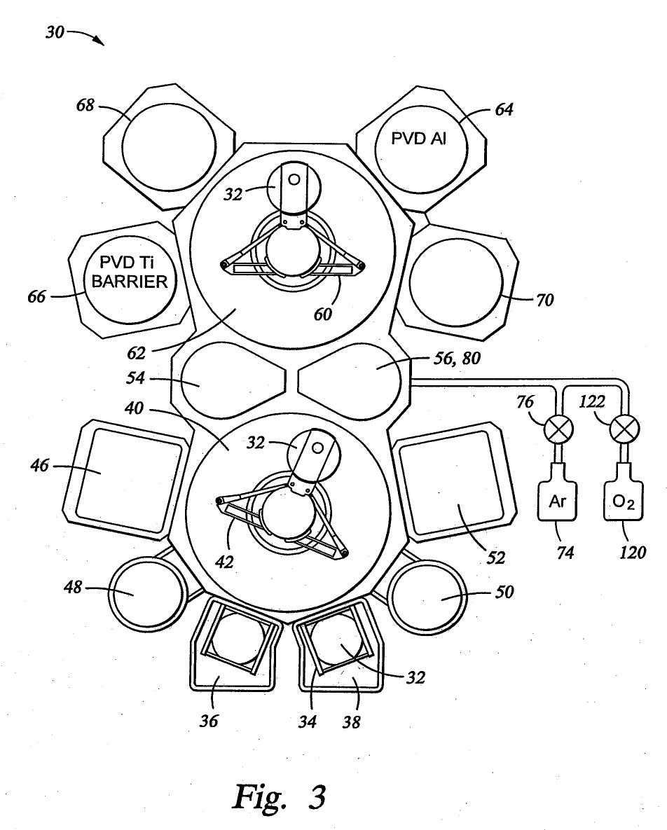

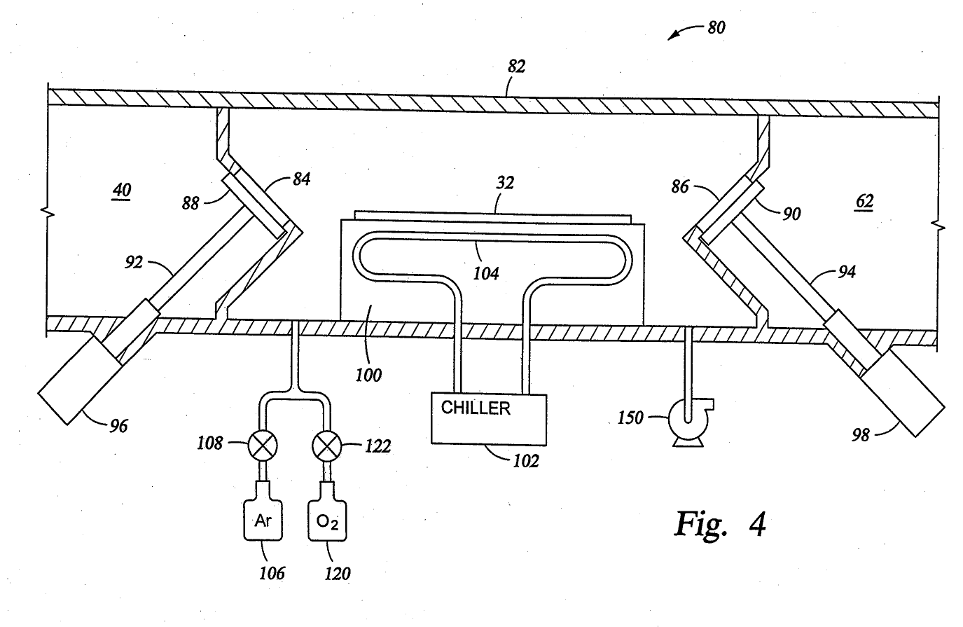

In one embodiment of achieving a controlled hot oxidation, as shown in FIGS. 3 and 4, an oxygen gas source 120 supplies oxygen gas (O₂) to the cool down chamber 80 through a gas valve 122. However, pure oxygen at the elevated temperatures of a hot wafer may produce too thick an oxide layer. Accordingly, in one embodiment, a substantial amount of an inactive gas such as argon is also supplied from the argon gas source 106 into the cool down chamber 80 during the oxygen cool down to promote thermal transfer during the cool down. The total argon/oxygen gas pressure may be approximately 2 Torr with about 0.01 to 0.5 Torr partial pressure of oxygen although an oxygen partial pressure of above 0.1 Torr has proven beneficial. Although the wafer 32 is supported on the water-cooled pedestal 32 at about 22° C. during cool down, it is believed that the cooling is predominantly convective cooling through the ambient gas to the pedestal 32. A typical cool down rate with this total pressure is about 10° C./s.

The partial pressure of oxygen in the cool down chamber 80 causes the upper surface of the generally planar unpatterned aluminum layer 18 to oxidize and form an aluminum oxide layer 114 illustrated in the cross-sectional view of FIG. 6. With aluminum deposition conditions similar to that producing the comparative data of FIG. 5, the oxygen-cooled native oxide of the invention is shown to have a thickness of about 2 nm compared to 4.2 nm for a conventional native oxide formed in air after argon cooling of the wafer. The partial oxidation of the aluminum layer 18 causes the oxide thickness to be substantially less than 10% of the field thickness of the aluminum layer 18 so that the conductance of the aluminum interconnect is not substantially affected. Furthermore, an interface 116 of the oxide layer 114 with the underlying aluminum layer 18 is sharp and abrupt across approximately a monolayer. It appears that the hot-grown oxide is dense and prevents further oxidation when the wafer is returned to air ambient at below 100° C. The air ambient contains a large fraction of nitrogen and significant amount of water vapor even in the dry air of a clean room. Both components may affect the air oxidation. The AFM profile of oxygen-cooled oxide is shown in FIG. 6. The maximum peak-to-valley roughness is reduced to Rₘₐₓ=54.5 nm and the RMS roughness to Rᵣₘₛ=11.6 nm. Compared to the conventional AFM profile, the deep grooves are removed and the roughness is decreased. The grain size appears to be about the same although the grain boundaries are more distinct in the argon-only cooling. Numerical data of the comparative argon-cooled film and the inventive oxygen-cooled film are presented in TABLE 1. The sheet resistance does not greatly vary but the resistance uniformity significantly improves. The reflectivity at optical wavelengths of both 436 and 480 nm increases with oxygen-cooling.

TABLE 1

| | | Sheet | | |
|---|---|---|---|---|
| | | Resistance | | |
| | Sheet | Non- | | |
| | Resistance | uniformity | Reflectivity | Reflectivity |
| | (ohm/sq) | (%) | (436 nm) | (480 nm) |
| Argon Cool | 0.03263 | 1.75 | 167.2 | 187.5 |
| Oxygen Cool | 0.03271 | 1.06 | 187.8 | 207.6 |

The oxygen cool down should be performed after completion of the aluminum sputtering but prior to etching to form the patterned horizontal interconnects and prior to deposition of other significant layer on the aluminum layer 18 affecting the aluminum oxidation, such as the anti-reflective coating 22. The aluminum oxide layer 114 is insulating and will need to be removed prior to any electrical contacts to the upper surface of the aluminum layer but the removal is no different than the removal of the native oxide.

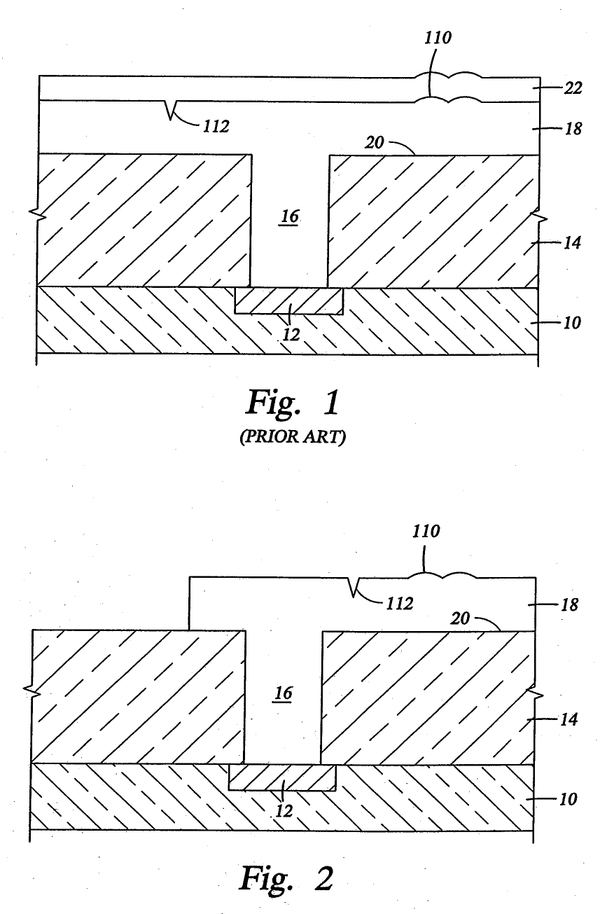

The hot controlled oxidation lessens the depth of the grooves 112 and levels out the hillocks 110 of FIGS. 1 and 2 as well as to decrease the grain size. The precise mechanisms are not completely understood. It seems that hot oxidation relieves stress, possibly by promoting surface diffusion along nascent grain boundaries activated by the oxidation energy. Oxidation in highly pure oxygen produces better oxide than oxidation in air containing both water vapor and a high fraction of nitrogen. One measure of the oxidizing purity is that active components of the oxidizing ambient, that is, other than inactive gases such as argon and helium, are greater than 99% oxygen. It should be mentioned that oxygen may be in the form of ozone (O₃).

The preferred partial pressure of oxygen during cool down is between 0.1 and 0.5 Torr although a wider acceptable range for the oxygen partial pressure depending upon process conditions is 0.1 to 1 Torr. Significantly higher oxygen pressures when the wafer is hot would likely produce an unduly thick oxide layer. The relatively high partial pressure of argon, at least twice that of oxygen, when the total pressure is 2 Torr allows fast cooling rates. The total pressure may be in a range above 1 Torr but it is preferred that it is no more than 5 Torr. It is anticipated that the amount of argon could be reduced or even eliminated with little direct effect on the oxidation. However, with reduced argon, the cooling rate is decreased so that oxidation continues for longer periods at the higher temperatures and also decreases the throughput. Helium could be substituted for argon as the convective cooling gas.

It is appreciated that the oxygen-based cooling can be performed in another valved chamber other than the pass through chamber and associated with a transfer chamber also associated with the sputter chamber so that the air pressure between deposition and oxidation is less than 1 microTorr.

It is also appreciated that the aluminum oxidation can be performed in a chamber designed for controlled oxidation and not relying upon cool down from sputtering temperatures.

The use of oxygen in semiconductor sputtering equipment is unusual and potentially causes problems Conventionally, all chambers on the Endura platform including the pass through chambers are supplied from a set of common gas sources connected to a gas distribution panel adjacent the platform. It is greatly desired to prevent oxygen from diffusing back along the argon gas lines into the sputter chambers or even into the high-vacuum transfer chamber. Experience has shown that wafers exposed to residual oxygen in the high-vacuum transfer chamber before being placed in an aluminum sputtering chamber exhibit severe voids in filling high-aspect ratio vias.

The software for the platform control should include an interlock to prevent the slit valves between the sputter chambers and the associated high-vacuum transfer chamber from opening at the same time as that the slit valve between the cool down chamber and the high-vacuum chamber transfer chamber is open.

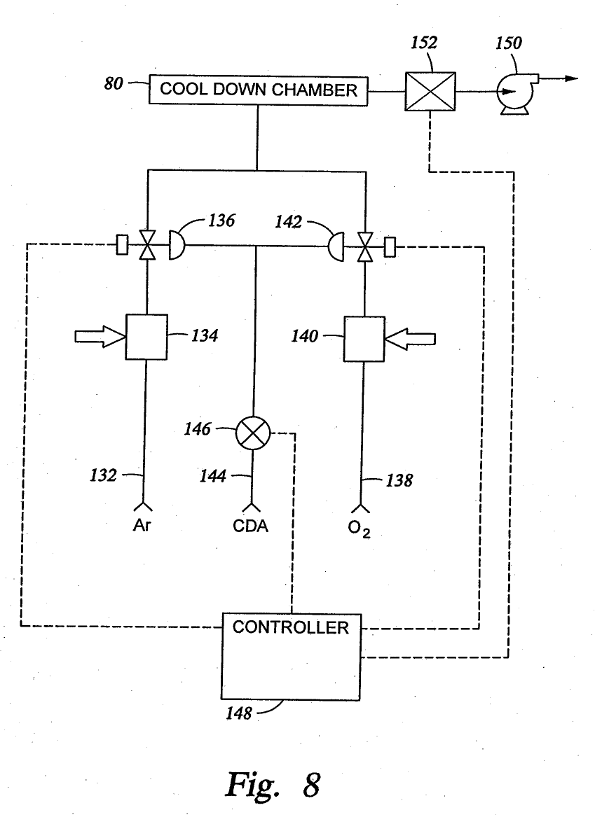

If the argon is supplied from a common source to the cool down chamber and the sputter chambers, the valves for the supply of argon and oxygen into the cool down chamber should not be opened at the same time. That is, argon and oxygen are separately pulsed into the cool down chamber and preferably the argon is pulsed first. If the cool down chamber is not pumped during cool down, the amounts of argon and oxygen initially pulsed into the cool down chamber determine the argon and oxygen partial pressures in the cool down chamber throughout cool down. One embodiment is illustrated in the schematic diagram of FIG. 8 of a gas supply system to the cool down chamber 80. Argon is supplied from an argon line 132 and its flow is metered by a manual needle valve 134 and gated by an electro-pneumatic valve 136. Similarly, oxygen is supplied from an oxygen line 138 and its flow is metered by a manual needle valve 140 and gated by an electro-pneumatic valve 142. The outputs of the electro-pneumatic valves 136, 142 are supplied into the cool down chamber 80.

The electro-pneumatic valves 136, 142 each include two stages of valves. A first valve, typically actuated by an electrically driven solenoid, gates the supply of clean dry air (CDA) supplied from a clean dry air line 144 through a gate valve 146. A second valve, actuated by the gated clean dry air, opens and closes the flow of the argon or oxygen through the electro-pneumatic valve. The electro-pneumatic valves 136, 142 themselves perform no effective metering. A controller 148 issues electrical control signals to open the supply of clean dry air through the CDA gate valve 146 and to open and close the two electro-pneumatic valves 136, 142. At known argon and oxygen pressures, the amount of argon or oxygen supplied into the cool down chamber is determined by the amount of time the controller 148 opens the respective electro-pneumatic valves 136, 142. As mentioned previously, the controller 148 should assure that the two electro-pneumatic valves 136, 142 not be open at the same time. Also, the controller 148 should first open and close the argon electro-pneumatic valve 136 before opening the oxygen electro-pneumatic valve 142. The toggling of the gas supplies substantially prevents oxygen from back flowing through the argon pneumatic-valve 136 and needle valve 134 towards the argon source and to the sputter chambers. The argon electro-pneumatic valve 136 should not be reopened until the cool down chamber 80 has been purged of oxygen.

Oxygen isolation could be further improved by a roughing pump 150 that is dedicated to the cool down chamber 80 and connected to it through a gate valve 152. The roughing pump 150 is not used for rough pumping the sputtering chambers or the high-vacuum transfer chambers. The controller 148 shuts the gate valve 152 while the argon and oxygen are being injected into the cool down chamber 80 and during the subsequent cool down. The roughing pump exhausts the cool down chamber 80 after cool down. The cryopumps associated with the transfer chambers pumps the cool down chamber 80 through an opened slit valve to ultra-high vacuum.

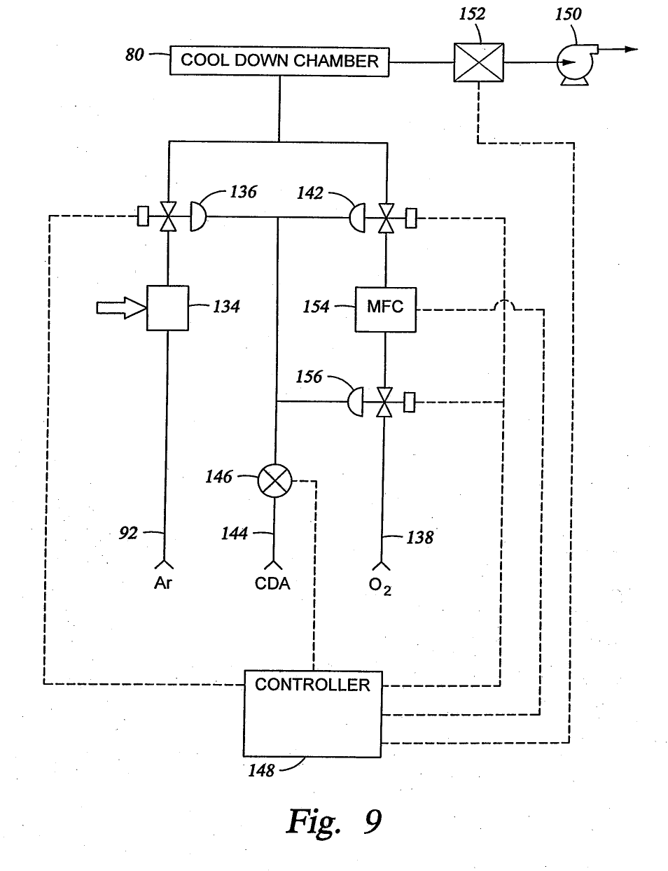

Control of the hot-oxidation can be improved, as illustrated in the schematic diagram of FIG. 9, by replacing the oxygen needle valve 140 with a mass flow controller 154 electrically controlled by the controller 148. Another electro-pneumatic valve 156 allows the mass flow controller 154 to be isolated. A mass flow controller could also replace the argon needle valve 134 but generally the argon flow and pressure for cool down do not require close control or adjustment.

The invention thus allows a significant improvement in the quality of an aluminum metallization with a small increase of equipment complexity and cost and with virtually no impact on throughput.

1. A method of depositing aluminum for an integrated circuit interconnect, comprising the steps of:
sputter depositing an unpatterned aluminum layer onto a substrate held at an elevated temperature; and
then partially oxidizing the unpatterned aluminum layer in an ambient containing an active gas consisting essentially of oxygen.

2. The method of claim 1, wherein the oxidizing is performed in a cooling step in which the substrate is cooled.

3. The method of claim 2, wherein the ambient additionally contains more argon than oxygen.

4. The method of claim 2, comprising the steps of first supplying and then terminating supplying argon and then beginning to supply oxygen into a chamber in which the substrate is cooled.

5. The method of claim 2, wherein the ambient additionally contains argon to a total pressure of argon and oxygen of no more than 5 Torr.

6. The method of claim 2, wherein the cooling step cools the substrate to no more than 100° C.

7. The method of claim 2, wherein the elevated temperature is at least 300° C.

8. The method of claim 2, further comprising thereafter photolithographically defining the aluminum layer.

9. The method of claim 2, wherein the ambient includes a partial pressure of oxygen of between 0.01 and 1 Torr.

10. The method of claim 9, wherein the partial pressure of oxygen is at least 0.1 Torr.

11. The method of claim 9, wherein the partial pressure of oxygen is no more than 0.5 Torr.

12. The method of claim 9, wherein the ambient additional includes argon for a total pressure of oxygen and argon of between 1 and 5 Torr.

13. The method of claim 2, further comprising loading substrates from a cassette disposed adjacent a first transfer chamber held at a first base pressure,
wherein the sputtering is performed in a sputter chamber adjacent a second transfer chamber held at a second base pressure less than the first base pressure, and
wherein the cooling is performed in a pass through chamber accessible from both the first and second transfer chambers.

14. The method of claim 2, further comprising preventing a chamber containing the wafer during the cooling being in simultaneous communication with the interior of a sputter chamber in which the sputtering is performed.

15. A sputtering platform, comprising:
a first transfer chamber having a first robot disposed therein;
a load lock chamber coupled through a valve to the first transfer chamber for containing a cassette carrying a plurality of substrate and accessible by the first robot;
a second transfer chamber having a second robot disposed therein;
a sputter chamber configured for sputtering aluminum coupled through a valve to the second transfer chamber;
a pass through chamber coupled to the first and second transfer chambers through respective valves and accessible by the first and second robots; and
a source of oxygen controllably supplied into the pass through chamber.

16. The platform of claim 15, further comprising a source of argon controllably supplied into the pass through chamber.

17. The platform of claim 16, further comprising control means to alternate supply of argon and oxygen into the pass through chamber.

18. The platform of claim 16, wherein the pass through chamber acts as a cool down chamber.

19. The platform of claim 15, further comprising a pump connected to the pass through chamber but not to the sputter chamber.

20. A sputtering platform, comprising:
a transfer chamber including a robot;
a sputter chamber configured for sputtering aluminum onto a substrate connected to the transfer chamber through a first valve and accessible by the robot;
a cool down chamber for containing the substrate therein to cool it, connected to the transfer chamber through a second valve, and accessible by the robot; and
a source of oxygen controllably supplied to the cool down chamber.

21. The platform of claim 20, further comprising a source of argon controllably supplied to the cool down chamber.
